(19) United States
(12) Patent Application Publication
(10) Pub. No.: US 2026/0324178 A1
(43) Pub. Date: Oct. 15, 2026

(54) LAMINATE, TRANSISTOR, METHOD FOR MANUFACTURING LAMINATE, AND METHOD FOR MANUFACTURING TRANSISTOR

(71) Applicant: NIKON CORPORATION, Tokyo (JP)

(72) Inventor: Yusuke KAWAKAMI, Yokohama-shi (JP)

(73) Assignee: NIKON CORPORATION, Tokyo (JP)

(21) Appl. No.: 19/629,203

(22) Filed: Mar. 26, 2026

Related U.S. Application Data
(63) Continuation of application No. PCT/JP2024/030019, filed on Aug. 23, 2024.
(63) Continuation of application No. PCT/JP2023/034991, filed on Sep. 26, 2023.

(51) Int. Cl. H10K 10/84; H10K 10/46; H10K 71/60

(52) U.S. Cl. CPC H10K 10/84; H10K 10/466; H10K 71/60

(57) ABSTRACT

A laminate including a substrate, an amine generation layer, a copper wire layer, and a copper wire protective layer in this order.

### TECHNICAL FIELD

The present invention relates to a laminate, a transistor, a method for manufacturing a laminate, and a method for manufacturing a transistor.

Priority is claimed on Japanese PCT/JP2023/034991, filed Sep. 26, 2023, the content of which is incorporated herein by reference.

### BACKGROUND ART

Recently, in the manufacturing of miniaturized devices such as a semiconductor element, an integrated circuit, and a device for an organic EL display, a method in which patterns having different surface characteristics are formed on a substrate and a miniaturized device is produced using a difference in surface characteristics has been proposed.

An example of a method for forming patterns using a difference in surface characteristics on a substrate is a method in which a region where a chemically active substituent has been generated is formed in a part of a substrate. This method makes it possible to stick a metallic material, an organic material, or an inorganic material to a part of a substrate.

Electroless plating is a technique for forming a metal film by sticking a metallic material onto a substrate. For example, Patent Document 1 discloses a technique for forming a fine wire by electroless plating. Specifically, Patent Document 1 discloses that optical patterning by etching or lift-off is performed on one surface from a plated state using a catalytically active layer and a photoresist.

### CITATION LIST

### Patent Document

Patent Document 1: Japanese Unexamined Patent Application, First Publication No. 2006-2201

### SUMMARY OF INVENTION

A first aspect of the present invention is a laminate including a substrate, a base film layer, a copper wire layer, and a copper wire protective layer in this order, in which the base film layer includes an amine generation layer.

### BRIEF DESCRIPTION OF DRAWINGS

FIG. 1 A schematic cross-sectional view of one example of a laminate of the present embodiment.

FIG. 2 A schematic cross-sectional view of one example of a transistor of the present embodiment.

FIG. 3 A schematic view showing steps of one example of a method for manufacturing a laminate of the present embodiment.

FIG. 4 A schematic view showing steps of one example of the method for manufacturing a laminate of the present embodiment.

FIG. 5 A schematic view showing steps of one example of the method for manufacturing a laminate of the present embodiment.

FIG. 6 A view showing source/drain electrode structures manufactured in Example 1.

FIG. 7 A view showing the results of transmission characteristics evaluation of a transistor manufactured in Example 1.

FIG. 8 A view showing a fine wire manufactured in Example 2.

FIG. 9 A view showing a source/drain electrode structure manufactured in Example 2.

FIG. 10 A view showing the results of transmission characteristics evaluation of a transistor manufactured in Example 2.

FIG. 11 A view showing relationships between an exposure dose and a photoreaction rate by UV irradiation regarding a monomer NBC and a monomer iPrNBC.

FIG. 12 A view showing analysis results when NiP plating has been performed on individual amine generation layers having different exposure doses regarding a polymer NBC and PiPrNBC-AEMA.

### DESCRIPTION OF EMBODIMENTS

Hereinafter, a laminate and a method for manufacturing a laminate of the present embodiment will be described with reference to drawings.

In all of the following drawings, the dimension, ratio, or the like of each constituent is appropriately varied to facilitate understanding of the drawings.

### Laminate

One aspect of the present invention is a laminate including a substrate, an amine generation layer, a copper wire layer, and a copper wire protective layer in this order.

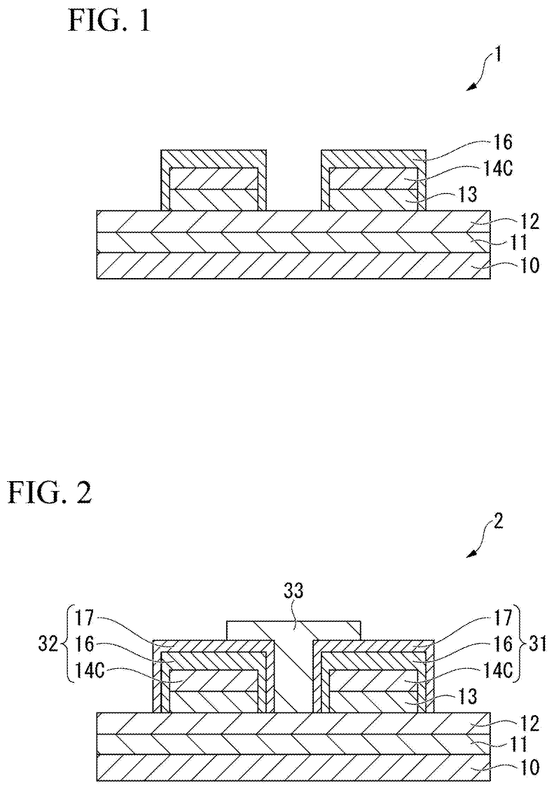

FIG. 1 is a schematic cross-sectional view of a laminate 1 of the present embodiment. The laminate 1 includes a substrate 10, an amine generation layer 12, copper wire layers 14C, and copper wire protective layers 16.

In FIG. 1, a gate insulation layer 11 and first catalyst layers 13 are an optional configuration.

The amine generation layer 12 and the optional gate insulation layer 11 are formed on one entire main surface of the substrate 10. The copper wire layers 14C are a fine copper wire pattern formed on the amine generation layer 12. The copper wire layers 14C are protected with the copper wire protective layers 16. The copper wire protective layer 16 is a conductive protective film.

The laminate 1 can be suitably used as a pattern electrode for a transistor. In the case of using the laminate 1 as a pattern electrode for a transistor, the copper wire layers 14C configure a source electrode and a drain electrode, respectively.

As the substrate 10, any of a light-permeable substrate or a light-impermeable substrate can be used. For example, inorganic materials such as glass, quartz glass, silicon, and silicon nitride, organic polymers (resins) such as an acrylic resin, a polycarbonate resin, and a polyester resin such as PET (polyethylene terephthalate) or PBT (polybutylene terephthalate), and the like can be used.

An amine that the amine generation layer 12 contains is, for example, a primary amine (—NH₂—) or a secondary amine (—NH—).

In a case where the laminate 1 configures a bottom gate-type transistor, the gate insulation layer 11 is preferably provided on the substrate 10. The gate insulation layer 11 contains, for example, a methoxysilane coupling agent and 4-methoxychalcone.

Furthermore, as an optional configuration, a metal wire pattern including a gate electrode may be provided on a part or all of one main surface of the substrate 10 and below the gate insulation layer 11. Examples of this metal wire pattern include conductive materials containing molybdenum and aluminum, and the metal wire pattern is a fine metal wire of MAM (a three-layer structure of Mo (molybdenum), Al (aluminum), and Mo (molybdenum)).

The copper wire layers 14C are metal wires formed on a surface of the amine generation layer 12. The laminate 1 is manufactured by a method for manufacturing a laminate of the present embodiment, which will be described below. In the manufacturing method of the present embodiment, as a trace of performing a step of removing the first catalyst layers present in opening portions of a photoresist layer, the first catalyst layers 13 may remain below the copper wire layers 14C. The first catalyst layer 13 may be a layer containing palladium.

The copper wire layer 14C is protected by the copper wire protective layer 16 in the upper surface and the side surfaces. The copper wire protective layer 16 is a conductive protective film, and a specific constituent material is nickel phosphorus, nickel boron, or palladium.

In a case where the laminate 1 configures a transistor, gold-plated layers are preferably provided on the copper wire protective layers.

FIG. 2 shows a schematic cross-sectional view of a transistor including the laminate of the present embodiment and an organic semiconductor layer.

In FIG. 2, a transistor 2 includes the substrate 10, the amine generation layer 12, a source electrode 32, a drain electrode 31, and an organic semiconductor layer 33.

The electrode 32 and the drain electrode 33 each include the copper wire layer 14C, the copper wire protective layer 16, and a gold-plated layer 17.

Furthermore, the transistor 2 shown in FIG. 2 includes the gate insulation layer 11 and the first catalyst layers 13.

The gold-plated layer 17 is a metal wire that is formed by electroless plating like the copper wire layer 14C.

The copper wire layer 14C serves as a first electrode that configures the source electrode 32 or the drain electrode 31, and the gold-plated layer 17 serves as a second electrode that configures the source electrode 32 or the drain electrode 31.

A constituent material of the second electrode is preferably gold (work function: 5.4 eV), which is a metallic material having a work function that allows easy electron transport (or hole transport), in terms of a relationship with the HOMO/LUMO level of a material that forms the organic semiconductor layer 33.

For the above-described reason, conventionally, wires for which nickel phosphorus is used as the first electrode and gold is used as the second electrode have been studied. However, when nickel phosphorus is used, since the resistance becomes high in a case where a transistor is enlarged, there has been a demand for a material having lower resistance.

As a result of using copper for the first electrode with an intention of manufacturing a transistor having low resistance, the present inventors faced a problem of the occurrence of migration and the exposure and oxidation of a copper wire during transistor driving in the case of coating the copper wire in the first electrode with gold.

Therefore, the present inventors recalled the protection of a copper wire layer with a copper wire protective layer and completed the present invention.

In the laminate of the present embodiment, since the copper wire layers are protected with the copper wire protective layers, it is possible to provide a transistor having reduced resistance with no occurrence of migration even in a case where the transistor is driven after the gold-plated layers are further formed.

An organic semiconductor material that is used for the transistor is not particularly limited, and it is possible to use p-type semiconductors such as copper phthalocyanine (CuPc), pentacene, rubrene, tetracene, and P3HT (poly(3-hexylthiophene-2,5-diyl)); n-type semiconductors such as fullerenes such as C60 and perylene derivatives such as PTCDI-C8H (N,N′-dioctyl-3,4,9,10-perylene tetracarboxylic diimide); and Ph-BTBT-10 (2-decyl-7-phenyl [1]benzothieno [3,2-b][1]benzothiophene). Among these, soluble pentacenes such as TIPS pentacene (6,13-bis(triisopropylsilylethynyl)pentacene), organic semiconductor polymers such as P3HT, or Ph-BTBT-10 are soluble in organic solvents such as toluene, are capable of forming organic semiconductor layers by a wet step, and are thus preferable. The HOMO level of TIPS pentacene is 5.2 eV, and the HOMO level of Ph-BTBT-10 is −5.6 eV.

### Method for Manufacturing Laminate

A method for manufacturing a laminate, which is one aspect of the present invention, will be described using drawings.

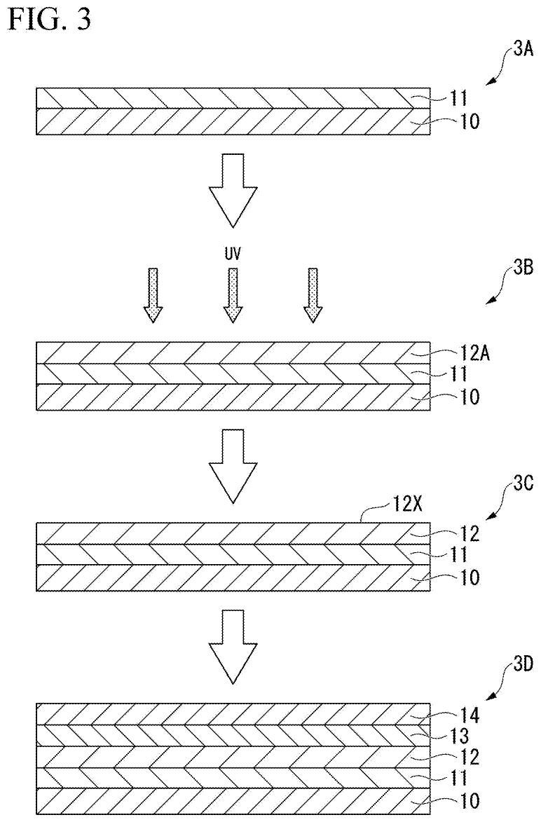

In FIG. 3, a step indicated by reference sign 3A is an optional step; however, in the case of manufacturing a laminate configuring a transistor, it is preferable to form the gate insulation layer 11 on a surface of the substrate 10.

The gate insulation layer 11 can be formed by applying, for example, a methoxysilane coupling agent to one entire main surface of the substrate 10. The gate insulation layer 11 is preferably formed by applying the methoxysilane coupling agent, then, further applying a photosensitive polymer material such as 4-methoxychalcone, and irradiating the methoxysilane coupling agent and the photosensitive polymer material with ultraviolet rays.

Furthermore, as an optional step, a step of forming a metal wire pattern on a part or all of one main surface of the substrate 10 and below the gate insulation layer 11 may be provided. Examples of this metal wire pattern include conductive materials containing molybdenum and aluminum, and a fine metal wire of MAM (a three-layer structure of Mo (molybdenum), Al (aluminum), and Mo (molybdenum)) may be formed.

Next, as indicated by reference sign 3B in FIG. 3, a photosensitive surface treatment agent is applied onto the substrate 10 or the optionally-formed gate insulation layer 11 to form a photosensitive resin film 12A. The photosensitive resin film 12A is exposed, and the amine generation layer 12 having an amine generation region is formed in an exposure portion (reference sign 3C in FIG. 3).

The photosensitive resin film 12A may be fully exposed or pattern-exposed through a mask, but is preferably fully exposed from the viewpoint of forming the copper-plated layer on the entire surface of the substrate 10 in the following step.

The photosensitive surface treatment agent for forming the photosensitive resin film 12A is not particularly limited as long as a protective group is removed by light irradiation and an amine is generated in the material.

For example, a photosensitive surface treatment agent containing a photosensitive polymer 1 (poly(isopropyl nitrobenzyl carbamate)) shown below is preferable.

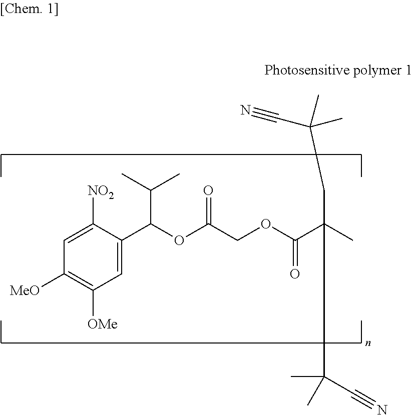

When the photosensitive resin film 12A is exposed, an amine is generated in the exposure portion, and the amine generation layer 12 having an amine generation region 12X is formed (reference sign 3C in FIG. 3). The amine is, for example, a primary amine (—NH₂—) or a secondary amine (—NH—).

Next, as indicated by reference sign 3D in FIG. 3, the first catalyst layer 13 is formed on the amine generation layer 12, and electroless plating is performed to form a copper-plated layer 14.

The first catalyst layer 13 is composed of a catalyst for electroless plating. The catalyst for electroless plating is a catalyst that reduces a metal ion contained in a plating solution for electroless plating, and examples thereof include silver or palladium.

An amino group is exposed on the surface of the amine generation layer 12. The amino group is capable of capturing and reducing the above-described catalyst for electroless plating. Therefore, the catalyst for electroless plating is captured on the amine generation layer 12, and the first catalyst layer 13 is formed. In addition, as the catalyst for electroless plating, a catalyst that can be supported by the amino group can be used.

The catalyst that is used to form the first catalyst layer 13 is not limited as long as the catalyst is a catalyst for electroless plating of copper and can be supported by an amine, but a metal catalyst having a pH of 3 to 12 at a measurement temperature of 20° C. is preferable. Examples of a commercially available product of such a catalyst include ACTIVATOR 7331 manufactured by Melplate Co., Ltd., which is a palladium catalyst having a pH of 3.5 to 6.5 at a measurement temperature of 20° C.

After the formation of the first catalyst layer 13 and before the formation of the copper-plated layer 14, a treatment for activating the first catalyst layer 13 is preferably performed as an optional step. The treatment for activating the first catalyst layer 13 refers to a treatment for reducing a metal chloride in the applied catalyst to a metal. The treatment is, for example, a treatment for reducing palladium chloride in the applied catalyst to metallic palladium or a treatment for reducing silver chloride to metallic silver.

In the treatment for activating the first catalyst layer 13, it is possible to use an acidic or alkaline solution called an accelerator, which is a known method, and specifically, a commercially available activator (for example, OPC-150 CRYSTER RW manufactured by Okuno Chemical Industries Co., Ltd.) may be used.

When the first catalyst layer 13 is activated, it is possible to turn the metal chloride into a metal and to improve the precipitation properties and adhesion of electroless plating.

After the formation of the first catalyst layer 13, electroless plating is performed to form the copper-plated layer 14. In the electroless plating, the substrate 10 is immersed in an electroless plating bath to reduce the metal ion on the surface of the first catalyst layer 13, and the copper-plated layer 14 is precipitated. Since the formation of the amine generation layer 12 makes a sufficient amount of the catalyst supported, it is possible to form the copper-plated layer 14 that is highly adhesive to the substrate 10.

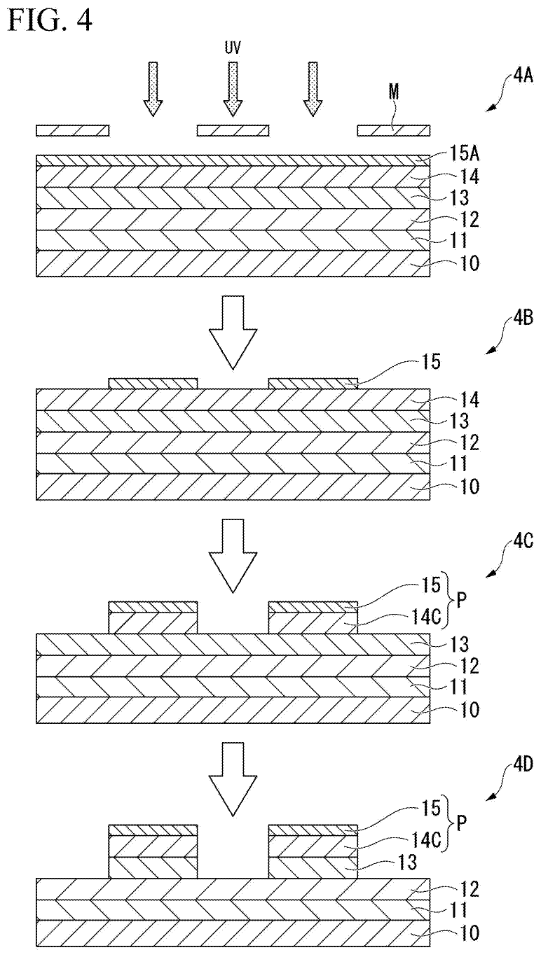

Next, as indicated by reference sign 4A in FIG. 4, a photoresist material 15A is applied onto the copper-plated layer 14, and the photoresist material 15A is pattern-exposed through a mask M to form exposure portions corresponding to a pattern of the copper wire layers. After that, a photoresist in unexposed portions is removed to form photoresist layers 15 as indicated by reference sign 4B in FIG. 4.

As the photoresist material 15A, a known material may be appropriately used, and for example, a positive-type photoresist material can be used.

Next, as indicated by reference sign 4C in FIG. 4, parts of the copper-plated layer 14 are removed to form the copper wire layers 14C. A preliminary pattern P including photoresist layers 15 on the copper wire layers 14C is formed by this step.

Next, as indicated by reference sign 4D in FIG. 4, a catalyst remover is brought into contact with the preliminary pattern P, and the first catalyst layer 13 present in photoresist opening portions is removed. Examples of a treatment method for removing the first catalyst layer 13 include a method in which the substrate 10 is immersed in the catalyst remover. As the catalyst remover, an aqueous solution containing an organic amine is preferable.

When the substrate 10 is immersed in an aqueous solution containing an organic amine, a metal catalyst configuring the first catalyst layer 13 and the organic amine form a complex, and the solubility of the metal catalyst improves, whereby the first catalyst layer 13 can be removed. At this time, since the photoresist layer 15 does not dissolve in the aqueous solution containing an organic amine, it is possible to remove the first catalyst layer 13 while the photoresist layer 15 is maintained.

As the aqueous solution containing an organic amine, an aqueous solution containing ethyleneamine is preferable. As such a commercially available product, for example, ICP POSTDIP RP manufactured by Okuno Chemical Industries Co., Ltd. can be used.

From the viewpoint of enhancing adhesion between the substrate 10 and the copper-plated layer 14 at the time of forming the copper-plated layer 14 on one entire main surface of the substrate 10, it is preferable to use a neutral metal catalyst having a pH of 3.5 to 6.5 at a measurement temperature of 20° C., the metal catalyst being capable of precipitating a large amount of copper. However, when a neutral metal catalyst remains, a metal component configuring the copper wire protective layer is excessively precipitated in a subsequent step of forming the copper wire protective layer, and the resistance value increases.

Therefore, while there is a need to remove the first catalyst layer 13 present in the photoresist opening portions, since the organic amine configuring the catalyst remover also forms a complex with copper, when the substrate 10 is simply immersed in the aqueous solution containing the organic amine, copper configuring the copper wire layer 14C elutes, and the copper wire is damaged.

In the present embodiment, when the catalyst remover is brought into contact with the preliminary pattern P, the photoresist layers 15 protect the copper wire layers 14C from the catalyst remover, and the first catalyst layers 13 can be removed without damaging the copper wire layers 14C.

While the upper surfaces of the copper wires in the copper wire layer 14C are protected by the photoresist layer 15, the side surfaces are not protected. However, since the area proportion of the side surfaces in the entire copper wire layer 14C is small, damage in the side surfaces due to the catalyst remover is less likely to appear.

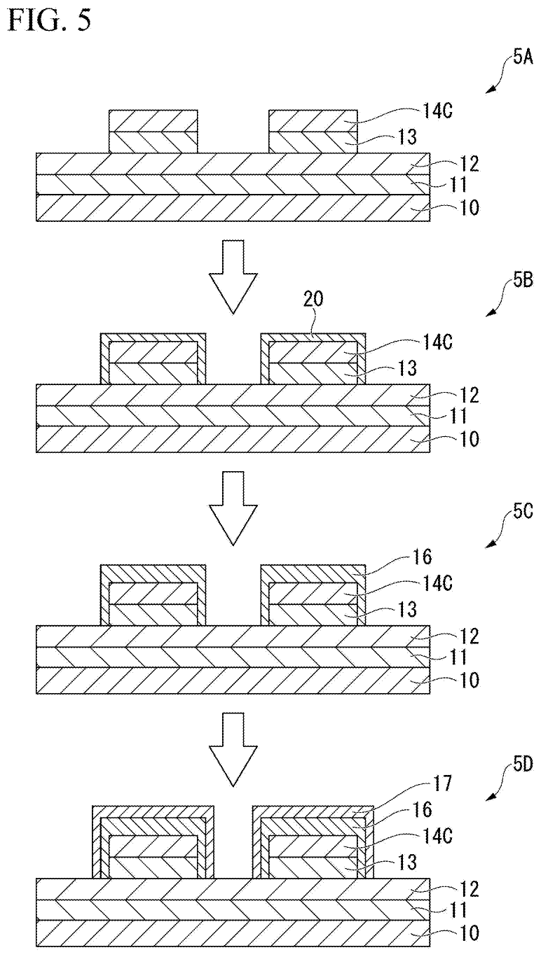

Furthermore, after the first catalyst layer 13 present in the photoresist opening portions is removed, the photoresist layers 15 are removed as indicated by reference sign 5A in FIG. 5. The photoresist layers 15 may be removed using a known developer.

Furthermore, as indicated by reference sign 5B in FIG. 5, second catalyst layers 20 are formed on the copper wire layers 14C, and electroless plating is further performed to form the copper wire protective layers 16 (reference sign 5C in FIG. 5). The copper wire protective layers 16 are formed to coat the upper surfaces and side surfaces of the copper wires in the copper wire layers 14C. The copper wire protective layer 16 is a conductive protective film, and a specific constituent material is nickel phosphorus, nickel boron, or palladium.

In order to form the copper wire protective layer 16, the second catalyst layer 20 is formed on the copper wire layer 14C. A catalyst configuring the second catalyst layer is a catalyst for electroless plating different from the catalyst for electroless plating configuring the first catalyst layer 13, and the catalyst that is used at this time is preferably an acidic metal catalyst having a pH of 2 or lower at a measurement temperature of 20° C. Examples of such a catalyst include ACTIVATOR 352 manufactured by Melplate Co., Ltd., which is an acidic palladium catalyst having a pH of 1 or lower at a measurement temperature of 20° C.

When the copper wire protective layers 16 are formed, gold configuring an electroless gold-plated layer to be formed in a subsequent optional step and the copper configuring the copper wire layer are less likely to migrate, and a short circuit attributed to reduced migration is less likely to occur.

Furthermore, as an optional step, gold-plated layers 17 may be formed (reference sign 3D in FIG. 5). The gold-plated layers 17 may be formed by the same electroless plating as for the copper-plated layer 14.

### Method for Manufacturing Transistor

A method for manufacturing a transistor of the present embodiment includes a step of performing all of the steps including the provision of the gold-plated layers by the above-described method for manufacturing a laminate of the present embodiment and then forming an organic semiconductor layer in contact with the mutually facing surfaces of a source electrode and a drain electrode.

### EXAMPLES

Hereinafter, the present invention will be more specifically described using examples, but the present invention is not limited to the following examples.

### Example 1

### Step of Forming Amine Generation Layer

A film of a cyclopentanone solution of MCSC ((E)-4-(3-(4-methoxyphenyl)acryloyl)phenyl (3-(trimethoxysilyl)propyl)carbamate) was formed on a thermal oxide film-attached silicon wafer by spin coating and surface-treated. Furthermore, a 5 wt % cyclopentanone solution of PMC (poly(4-methoxychalcone)) was applied thereto with a spin coater (MS-A150 manufactured by Mikasa Corporation) 1000 rpm) and then dried at 100° C. for 20 minutes. The film was irradiated with UV light having a wavelength of 365 nm at 1200 mJ/cm² and heated at 150° C. for 60 minutes, thereby producing a gate insulation layer, which was to serve as a base film. In the present Example 1, the silicon wafer functions as a gate electrode of a transistor.

The structures of MCSC and PMC are shown below, respectively.

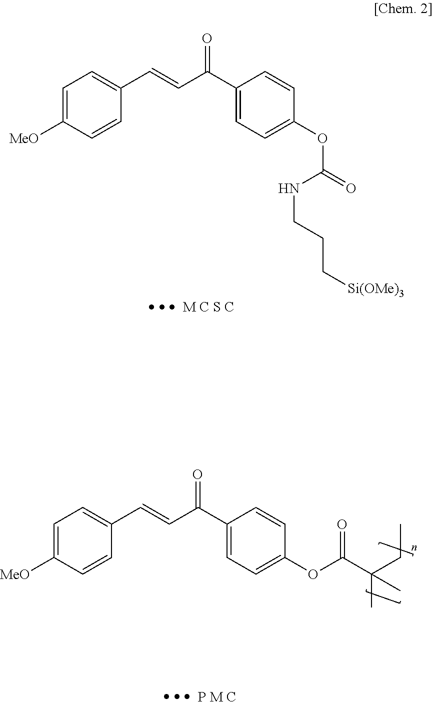

Next, a 0.3 wt % cyclopentanone solution of PiPrNBC-AEMA (polyisopropyl nitrobenzyl carbamate) was applied thereto with the spin coater (MS-A150 manufactured by Mikasa Corporation) at 1000 rpm and dried at 100° C. for 20 minutes, thereby forming a photosensitive polymer layer.

The structure of PiPrNBC-AEMA is shown below.

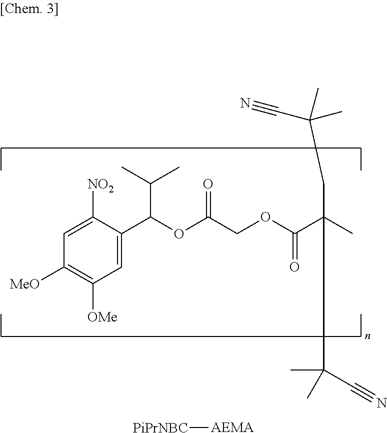

Next, a substrate having the photosensitive polymer layer formed on the entire surface was exposed to light having a wavelength of 365 nm at 1000 mJ/cm² to sensitize the photosensitive polymer layer, thereby forming an amine generation layer.

### Step of Forming Copper-Plated Layer

Next, the amine generation layer was immersed in a catalyst solution for electroless plating (MELPLATE ACTIVATOR 7331 manufactured by Meltex Inc.) at room temperature for 10 minutes to attach a catalyst (Pd) to an amine generation portion. After the surface was washed with water, the amine generation layer was immersed in a catalyst activation solution (OPC-150 CRYSTER RW manufactured by Okuno Chemical Industries Co., Ltd.) at room temperature for one minute, and the catalyst (Pd) was attached to the amine generation portion and activated. As a result, a first catalyst layer was formed. Subsequently, the first catalyst layer was immersed in an electroless plating solution (OPC COPPER HFS manufactured by Okuno Chemical Industries Co., Ltd.) at 40° C. for three minutes, and electroless copper was precipitated on the catalyst to produce a copper-plated layer.

### Photoresist Step

A photoresist (PFI-34 manufactured by Sumitomo chemical Company, Limited) was applied thereto with the spin coater (MS-A150 manufactured by Mikasa Corporation) at 1500 rpm and heated at 105° C. for eight minutes, thereby forming a photoresist layer. The photoresist layer was irradiated with UV light having a wavelength of 365 nm at 100 mJ/cm² through a photomask, photo-baked at 105° C. for three minutes, and then immersed in a developer (NMD-3, 2.38% of tetramethylammonium hydroxide, manufactured by Tokyo Ohka Kogyo Co., Ltd.) for one minute, thereby removing the photoresist in an exposure portion.

### Step of Forming Preliminary Pattern

The photoresist layer was heated at 105° C. for five minutes and immersed in a copper etchant (acetic acid/hydrogen peroxide/water=1/1/20) at 30° C. for 40 seconds, thereby partially removing the copper-plated layer. As a result, a preliminary pattern including the photoresist layer was formed on a copper wire layer.

### Step of Removing First Catalyst Layer

Subsequently, the copper wire layer was immersed in a catalyst remover (ICP POSTDIP RP-C manufactured by Okuno Chemical Industries Co., Ltd.) at 50° C. for 15 minutes, thereby removing palladium, which was the first catalyst layer present in a photoresist opening portion.

### Step of Removing Photoresist Layer

The substrate was immersed in a resist stripper (N-342 manufactured by Nagase ChemteX Corporation) at room temperature for four minutes, thereby removing the photoresist and producing a fine copper wire layer.

### Step of Forming Copper Wire Protective Layer

The substrate was immersed in a catalyst solution for electroless plating (MELPLATE ACTIVATOR 352 manufactured by Meltex Inc.) at 30° C. for 40 seconds, subsequently immersed in the catalyst remover (ICP POSTDIP RP-C manufactured by Okuno Chemical Industries Co., Ltd.) at 25° C. for one minute, and then immersed in an electroless plating solution (MELPLATE NI-867 manufactured by Meltex Inc.) at 73° C. for three minutes, and nickel phosphorus was precipitated on a copper plate to produce a fine plated wire including the copper wire protective layer, thereby obtaining a laminate.

### Gold Plating Step

The laminate was immersed in an electroless plating solution (FLASH GOLD NC manufactured by Okuno Chemical Industries Co., Ltd.) at 55° C. for four minutes, an immersion gold plate was precipitated to produce fine plated wires, and the fine plated wires were used as source/drain electrodes.

The surfaces of the electrodes were ultrasonic-washed (at 45 kHz for four minutes) sequentially with cyclopentanone, xylene, and IPA and heated and dried at 120° C. for 60 minutes. Furthermore, the surfaces were UV-washed for eight minutes, ultrasonic-washed (at 45 kHz for three minutes) in IPA, and heated and dried at 120° C. for 60 minutes. Next, the substrate was immersed in a 0.75 wt % ethanol solution of TFTFMBT (2,3,5,6-tetrafluoro-4-(trifluoromethyl)benzenethiol, manufactured by Tokyo Chemical Industry Co., Ltd.) at room temperature for five minutes, taken out, rinsed with toluene, and dried by blowing nitrogen thereto, thereby forming gold-thiol SAM films on the surfaces of the electrodes.

Subsequently, a 0.1/0.45% wt xylene solution of polystyrene (manufactured by Merck & Co., Inc.)/organic semiconductor (Ph-BTBT-10,2-decyl-7-phenyl [1] benzothieno [3,2-b][1] benzothiophene, manufactured by Tokyo Chemical Industry Co., Ltd.) was applied thereto with a heating-type spin coater at 145° C. and 3000 rpm and dried at 120° C. for 10 minutes and at 100° C. for 60 minutes, thereby producing an organic semiconductor layer and obtaining a transistor of Example 1.

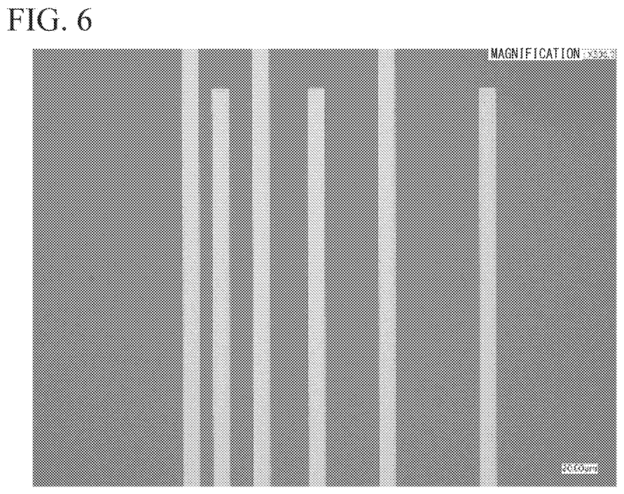

The structures of the produced source/drain electrodes are shown in FIG. 6. It was confirmed that in all shapes where the distance between the electrodes were set to 10, 20, 35, 50, and 80 um, respectively, fine details have been patterned.

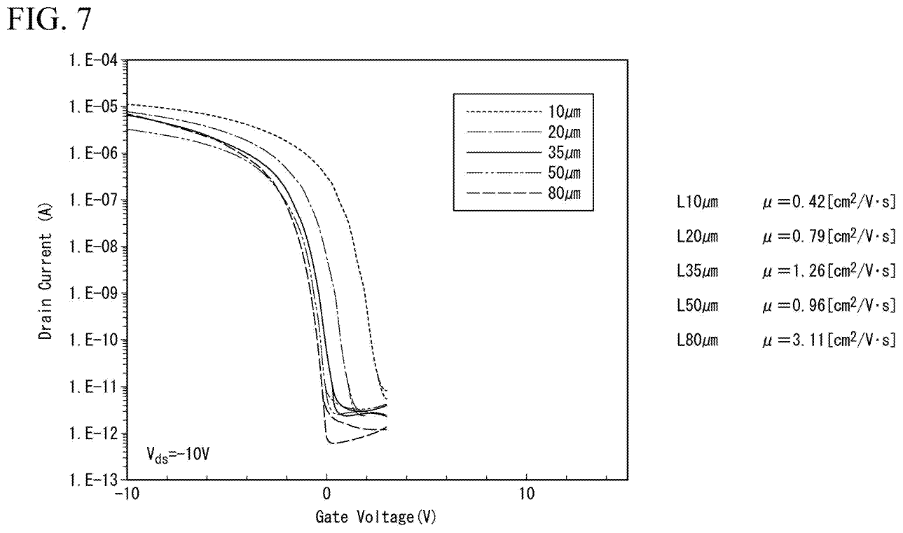

The results of the transmission characteristics evaluation of OTFTs (channel lengths L=10, 20, 35, 50, and 80 m, channel width W=500 m) shown in FIG. 7 are shown in FIG. 7. It was possible to confirm that regardless of the channel lengths, all of the transistors normally operated.

In Example 1, copper plates as thin as approximately 200 nm were used, and a decrease in conductivity due to a chemical solution is likely to have an influence. Here, palladium in the lower portions of the copper plates is reduced while the resists remain, whereby it is possible to laminate excellent Au plates with no damage on the copper plates. The sheet resistance is 0.19Ω/□ after copper plating, but can be maintained at 0.22Ω/□ after Au lamination.

### Comparative Example 1

A transistor of Comparative Example 1 was manufactured by the same method as in Example 1 except that the step of forming a photoresist layer was not performed, and a step of immersing the copper-plated layer in the catalyst remover (ICP POSTDIP RP-C manufactured by Okuno Chemical Industries Co., Ltd.) at 25° C. for two minutes was added before the formation of the copper wire protective layer on the copper-plated layer.

A decrease in the conductivity was confirmed from the sheet resistance being 0.38Ω/□ after copper plating and 0.72Ω/□ after Au lamination. It is confirmed that immersion in the catalyst remover with no resist protection has an influence on an increase in resistance value, and it is desirable to avoid the exposure of copper to a chemical solution before the application of the catalyst to the surface of the copper.

### Comparative Example 2

A transistor of Comparative Example 2 was manufactured by the same method as in Comparative Example 1 except that a step of immersing the copper-plated layer in the catalyst remover (ICP POSTDIP RP-C manufactured by Okuno Chemical Industries Co., Ltd.) at 25° C. for one minute was performed before the formation of the copper wire protective layer on the copper-plated layer.

A decrease in the conductivity was confirmed from the sheet resistance being 0.34Ω/□ after copper plating and 1.02Ω/□ after Au lamination. It is confirmed that immersion in the catalyst remover with no resist protection has an influence on an increase in resistance value, and it is desirable to avoid the exposure of copper to a chemical solution before the application of the catalyst to the surface of the copper.

### Comparative Example 3

A transistor of Comparative Example 3 was manufactured by the same method as in Comparative Example 1 except that a step of immersing the copper-plated layer in the catalyst remover (ICP POSTDIP RP-C manufactured by Okuno Chemical Industries Co., Ltd.) at 25° C. for four minutes was performed before the formation of the copper wire protective layer on the copper-plated layer.

A decrease in the conductivity was confirmed from the sheet resistance being 0.41Ω/□ after copper plating and 1.58Ω/□ after Au lamination. It is confirmed that immersion in the catalyst remover with no resist protection has an influence on an increase in resistance value, and it is desirable to avoid the exposure of copper to a chemical solution before the application of the catalyst to the surface of the copper.

The results of Example 1, Comparative Example 1, Comparative Example 2, and Comparative Example 3 were summarized in Table 1.

TABLE 1

Sheet resistance [Ω/□]

| | | After | After |
|---|---|---|---|
| | | copper | gold |
| | Experiment condition | plating | plating |
| Example 1 | Standard | 0.19 | 0.22 |
| Comparative | Catalyst removal after | 0.38 | 0.72 |
| Example 1 | resist peeling | | |
| Comparative | Catalyst removal after | 0.34 | 1.02 |
| Example 2 | resist peeling | | |
| Comparative | Catalyst removal after | 0.41 | 1.58 |
| Example 3 | resist peeling | | |

### Example 2

### Step of Forming Amine Generation Layer

A film of MAM (Mo/Al/MO) was formed in a dry manner on a PEN (TEONEX, polyethylene terephthalate, manufactured by Teijin Limited) film, and a fine wire of MAM was formed by photolithography to form a gate electrode. The gate electrode was UV/O3-washed for three minutes, and a 0.2 wt % cyclopentanone solution of MCSC ((E)-4-(3-(4-methoxyphenyl)acryloyl)phenyl (3-(trimethoxysilyl)propyl)carbamate) was formed by spin coating and surface-treated. Furthermore, a 12/1.2 wt % cyclopentanone solution of PVCI (polyvinyl cinnamate, manufactured by Merck & Co., Inc.)/MC (methoxychalcone, manufactured by Tokyo Chemical Industry Co., Ltd.) was applied thereto with a spin coater (MS-A150 manufactured by Mikasa Corporation) 2000 rpm) and then dried at 80° C. for 20 minutes. A film was irradiated with UV light having a wavelength of 365 nm at 624 mJ/cm², developed with PGMEA (propylene glycol monomethyl ether acetate, manufactured by Tokyo Chemical Industry Co., Ltd.), and heated at 150° C. for 120 minutes, thereby producing a gate insulation layer.

Next, a 0.3 wt % cyclopentanone solution of PiPrNBC-AEMA was applied thereto with the spin coater (MS-A150 manufactured by Mikasa Corporation) at 1000 rpm and dried at 100° C. for 20 minutes, thereby forming a photosensitive polymer layer.

Next, a substrate having the photosensitive polymer layer formed on the entire surface was exposed to light having a wavelength of 365 nm at 1000 mJ/cm² to sensitize the photosensitive polymer layer, thereby forming an amine generation layer.

### Step of Forming Copper-Plated Layer

Next, the amine generation layer was immersed in a catalyst solution for electroless plating (MELPLATE ACTIVATOR 7331 manufactured by Meltex Inc.) at room temperature for 10 minutes to attach a catalyst (Pd) to an amine generation portion. After the surface was washed with water, the amine generation layer was immersed in a catalyst activation solution (OPC-150 CRYSTER RW manufactured by Okuno Chemical Industries Co., Ltd.) at room temperature for one minute, and the catalyst (Pd) was attached to the amine generation portion and activated. Subsequently, the amine generation layer was immersed in an electroless plating solution (OPC COPPER HFS manufactured by Okuno Chemical Industries Co., Ltd.) at 40° C. for three minutes, and electroless copper was precipitated on the catalyst to produce a copper-plated layer.

### Photoresist Step

A photoresist (OFPR5000 manufactured by Tokyo Ohka Kogyo Co., Ltd.) was applied thereto with the spin coater (MS-A150 manufactured by Mikasa Corporation) at 1500 rpm and heated at 105° C. for five minutes, thereby forming a photoresist layer. The photoresist layer was irradiated with UV light having a wavelength of 365 nm at 27 mJ/cm² through a photomask, photo-baked at 105° C. for five minutes, and then immersed in a developer (NMD-3, 2.38% of tetramethylammonium hydroxide, manufactured by Tokyo Ohka Kogyo Co., Ltd.) for 25 seconds, thereby removing the photoresist in an exposure portion.

### Step of Forming Preliminary Pattern

The photoresist layer was heated at 105° C. for five minutes and immersed in a copper etchant (acetic acid/hydrogen peroxide/water=1/1/20) at 30° C. for 40 seconds, thereby partially removing the copper-plated layer. As a result, a preliminary pattern including the photoresist layer was formed on a copper wire layer.

### Step of Removing First Catalyst Layer

Subsequently, the copper wire layer was immersed in a catalyst remover (ICP POSTDIP RP-C manufactured by Okuno Chemical Industries Co., Ltd.) at 50° C. for 15 minutes, thereby removing palladium, which was the first catalyst layer present in a photoresist opening portion.

### Step of Removing Photoresist Layer

The substrate was immersed in a resist stripper (N-342 manufactured by Nagase ChemteX Corporation) at room temperature for four minutes, thereby removing the photoresist and producing a fine copper wire layer.

### Step of Forming Copper Wire Protective Layer

The substrate was immersed in a catalyst solution for electroless plating (MELPLATE ACTIVATOR 352 manufactured by Meltex Inc.) at 30° C. for 40 seconds, subsequently immersed in the catalyst remover (ICP POSTDIP RP-C manufactured by Okuno Chemical Industries Co., Ltd.) at 25° C. for one minute, and then immersed in an electroless plating solution (MELPLATE NI-867 manufactured by Meltex Inc.) at 73° C. for three minutes, and nickel phosphorus was precipitated on a copper plate to produce a fine plated wire including the copper wire protective layer, thereby obtaining a laminate.

### Gold Plating Step

The laminate was immersed in an electroless plating solution (FLASH GOLD NC manufactured by Okuno Chemical Industries Co., Ltd.) at 55° C. for four minutes, an immersion gold plate was precipitated to produce fine plated wires, and the fine plated wires were used as source/drain electrodes.

The surfaces of the electrodes were UV-washed for eight minutes, ultrasonic-washed (at 45 kHz for three minutes) in IPA, and heated and dried at 120° C. for 60 minutes. Next, the substrate was immersed in a 0.75 wt % ethanol solution of TFTFMBT (2,3,5,6-tetrafluoro-4-(trifluoromethyl)benzenethiol, manufactured by Tokyo Chemical Industry Co., Ltd.) at room temperature for five minutes, taken out, rinsed with toluene, and dried by blowing nitrogen thereto, thereby forming gold-thiol SAM films on the surfaces of the electrodes.

Subsequently, a 0.2/0.45 wt % xylene solution of polystyrene (manufactured by Merck & Co., Inc.)/organic semiconductor (Ph-BTBT-10,2-decyl-7-phenyl [1] benzothieno [3,2-b][1] benzothiophene, manufactured by Tokyo Chemical Industry Co., Ltd.) was applied thereto with a heating-type spin coater at 145° C. and 3000 rpm and dried at 120° C. for 10 minutes and at 100° C. for 60 minutes, thereby producing an organic semiconductor layer.

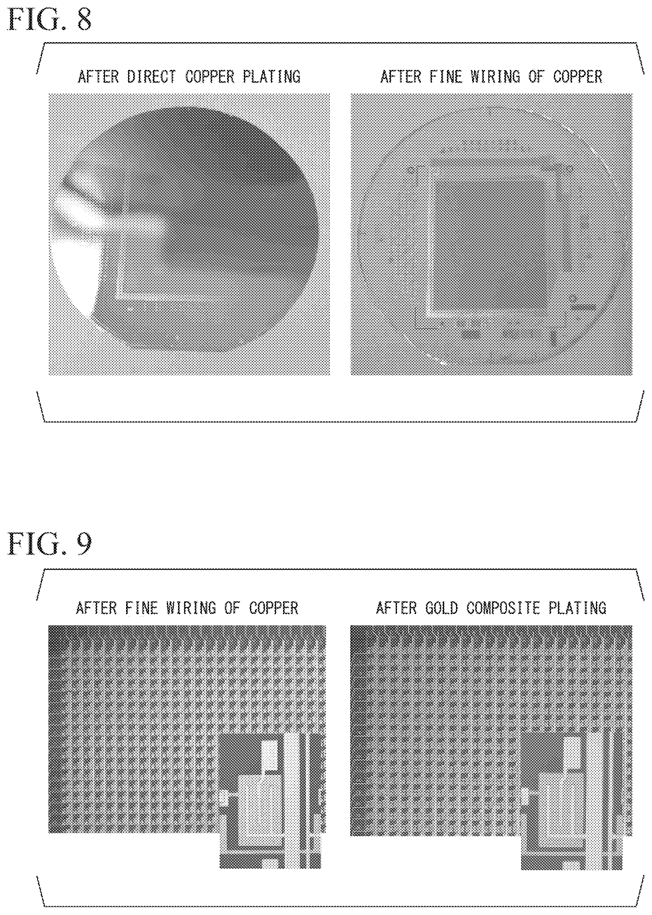

A fine copper wire processed on a film is shown in FIG. 8. A uniform and smooth copper plate can be processed even on a film, and the copper plate can be favorably patterned without peeling even after wiring.

The structures of the produced source/drain electrodes are shown in FIG. 9. It is shown that in all shapes where TFT was integrated, fine details have been patterned and Au composite plating has been selectively performed only in Cu-plated portions.

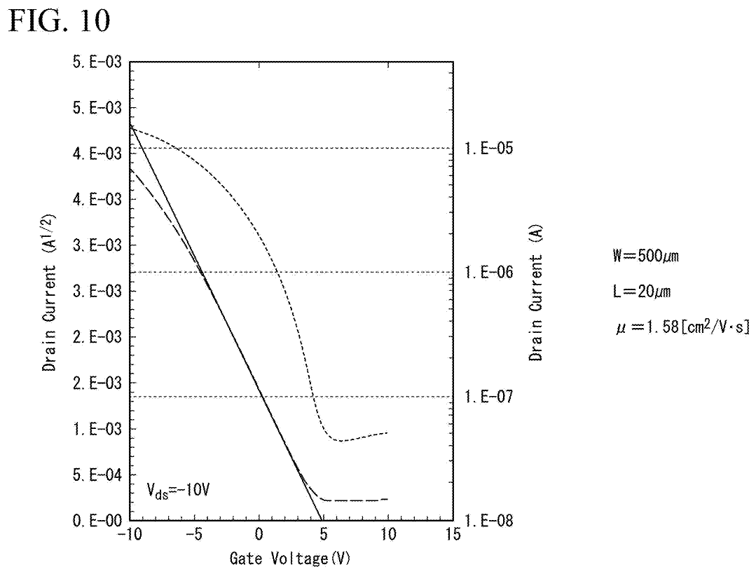

The results of the transmission characteristics evaluation of the produced OTFTs (channel length L=20 m, channel width W=500 m) are shown in FIG. 10. It is shown that the transistors normally operate even on the film substrates.

### Example 3

In the present example, the photoreaction characteristics of PiPrNBC-AEMA (polymer polyisopropyl nitrobenzyl carbamate-aminoethylmethylacrylate) used in the formation of the film of the photosensitive resin film 12A in Examples 1 and 2 were evaluated.

The photoreactivity evaluation was performed on monomer NBC (nitrobenzyl carbamate) and monomer iPrNBC (isopropyl nitrobenzyl carbamate). The structure of the monomer NBC is indicated by “NBC,” the structure of the monomer iPrNBC is indicated by “iPrNBC,” and the structures are shown below.

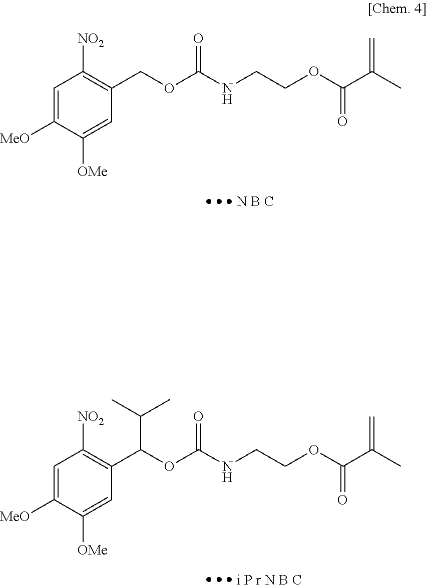 [SMILES: C=C(C)C(=O)OCCNC(=O)OCc1cc(OC)c(OC)cc1[N+](=O)[O-] ; C=C(C)C(=O)OCCNC(=O)OC(c1cc(OC)c(OC)cc1[N+](=O)[O-])C(C)C]

The monomer NBC and the monomer iPrNBC were adjusted to acetonitrile solutions having a concentration of 0.1 mMol/L, respectively, and loaded into quartz cells having an optical path length of 10 mm. These were irradiated with UV light having a wavelength of 365 nm. The photoreactivity was evaluated from an exposure dose by UV light and a decrease rate of each of the monomer NBC and the monomer iPrNBC. The decrease rate of each of the monomer NBC and the monomer iPrNBC was performed by high performance liquid chromatography-mass spectrometry (HPLC-MS).

The photoreaction rates (decrease rates) of each of the monomer NBC and the monomer iPrNBC for different exposure doses of UV irradiation are shown in Table 2 below.

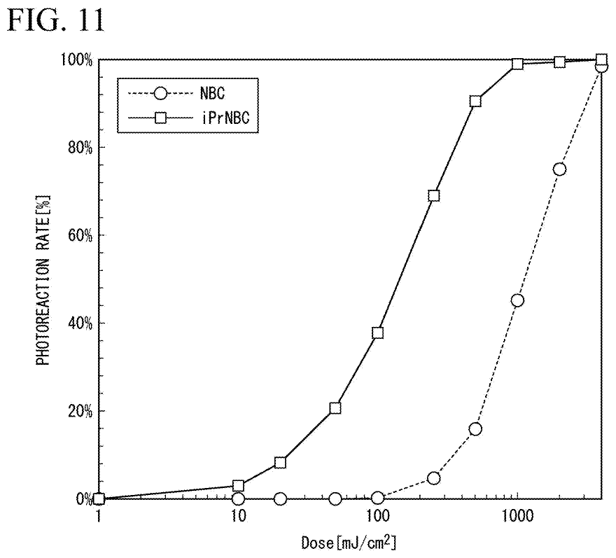

A graph of the results of Table 2 is shown in FIG. 11. FIG. 11 shows the relationships between the photoreaction rate (decrease rate) of each of the monomer NBC and the monomer iPrNBC and the exposure dose by UV irradiation. In the monomer NBC and the monomer iPrNBC, deprotection of a photosensitive leaving group is induced as the irradiance of UV increases. From the results shown in Table 2 and FIG. 11, it was confirmed that the irradiance of UV increases and NBC and iPrNBC decrease. Therefore, the decrease rates of NBC and iPrNBC were regarded as the photoreaction rates. Table 3 shows the calculation results of the reaction rate constant k (/s) and half-life t_{1/2} (s) of each of NBC and iPrNBC at the time of using a UV irradiation device having an illuminance of 21 mW/cm².

TABLE 2

| Dose | | |
|---|---|---|
| [mJ/cm²] | NBC | iPrNBC |
| 0 | 0% | 0% |
| 10 | 0% | 3% |
| 20 | 0% | 8% |
| 50 | 0% | 21% |
| 100 | 0% | 38% |
| 250 | 5% | 69% |
| 500 | 16% | 91% |
| 1000 | 45% | 99% |
| 2000 | 75% | 99% |
| 4000 | 98% | 100% |

TABLE 3

| | NBC | iPrNBC |
|---|---|---|
| k [/s] | 0.0092 | 0.1098 |
| t_{1/2} [s] | 75.3 | 6.3 |

From FIG. 11 and Table 2, it is found that iPrNBC has a higher photoreaction rate than NBC. In addition, from the reaction rate constants k and the half-life in Table 3, it was found that iPrNBC exhibits light sensitivity characteristics approximately 12 times larger than those of NBC.

Next, light sensitivity necessary for a underlayer for plating was evaluated using polymer NBC and PiPrNBC-AEMA. The structure of the polymer NBC is shown below.

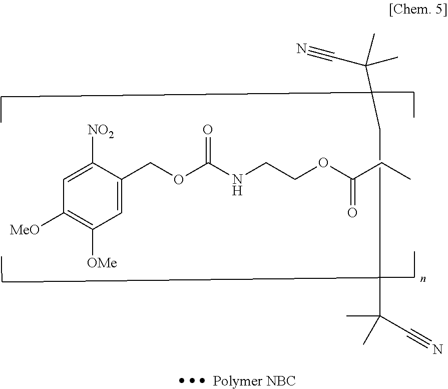

Photosensitive resin films were formed on film substrates using a cyclopentanone solution containing the polymer NBC dissolved therein and a cyclopentanone solution containing PiPrNBC-AEMA dissolved therein, respectively. These photosensitive resin films were exposed to light having a wavelength of 365 nm at different exposure doses, and amine generation layers were formed.

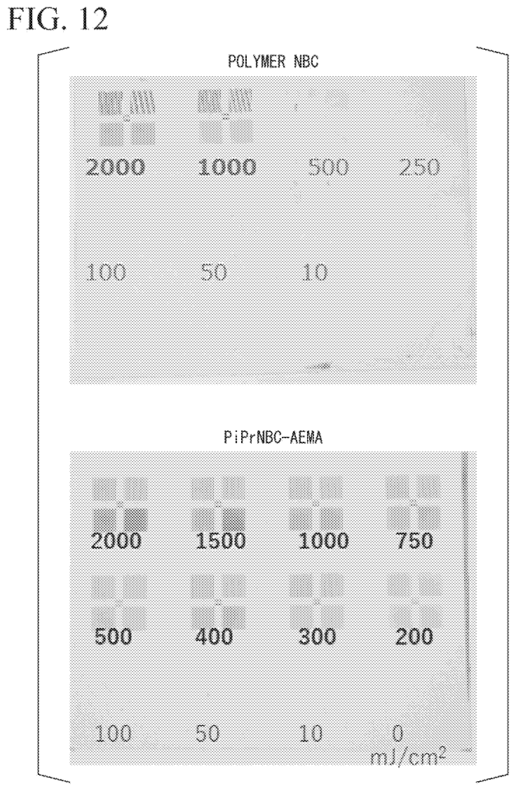

The photosensitive resin films for which the polymer NBC was used were exposed to light at exposure doses of 2000, 1000, 500, 250, 100, 50, and 10 mJ/cm². The photosensitive resin films for which PiPrNBC-AEMA was used were exposed to light at exposure doses of 2000, 1500, 1000, 750, 500, 400, 300, 200, 100, 50, 10, and 0 mJ/cm² to form amine generation layers. In addition, the precipitation result at the time of performing NiP plating on each amine generation layer having a different exposure dose is shown in FIG. 12.

The amine generation layers for which the polymer NBC was used required exposure at 1000 mJ/cm² or more for the precipitation of NiP plate, but precipitation occurred in the amine generation layers for which PiPrNBC-AEMA was used with exposure at 200 mJ/cm² or more. This is considered that PiPrNBC-AEMA has a superior light sensitivity to the polymer NBC and thus requires a smaller exposure dose for plating deposition as the amine generation layer. Therefore, amine generation layers for which PiPrNBC-AEMA is used can be plated even with short exposure, and high productivity can be thus expected.

While the evaluation was performed with NiP plating, but it is clear that the same tendency can be obtained even when evaluation is performed with copper plating.

From what has been described above, it was found that iPrNBC and PiPrNBC-AEMA did not only have high light sensitivity in a solution state but also obtained high photoreactivity even in the case of being used as photosensitive resin films. Photosensitive resin films for which iPrNBC and PiPrNBC-AEMA are used have high light sensitivity, are capable of efficiently generating an amine even at a small exposure dose, and are capable of further promoting a chemical reaction with an underlayer or a catalytic reaction and a chemical reaction for plating.

Hereinafter, a method for synthesizing PiPrNBC-AEMA will be described.

### Synthesis of isopropyl form, 1-(3,4-dimethoxyphenyl)-2-methylpropanone

In an argon atmosphere, iodine (6.22 g (0.0490 mol, 0.0374 eq.), Tokyo Chemical Industry Co., Ltd.), o-dimethoxybenzene (180.4 g (1.31 mol, 1.00 eq.), FUJIFILM Wako Pure Chemical Corporation), and isobutyric anhydride (414 g (2.62 mol, 2.00 eq.), Tokyo Chemical Industry Co., Ltd.) were mixed sequentially. The components were heated and stirred at an oil bath temperature of 170° C. for six hours and then stirred at room temperature for two days. After that, a mixture was vacuum-concentrated to obtain 294 g of a black oily substance. Water (1.6 L) and IPE: isopropyl ether (1.6 L) were added thereto, and the oily substance was transferred to a separatory funnel. An organic layer was separated, and IPE (800 mL) was then further extracted from a water layer. IPE was sequentially washed with a 5% sodium bicarbonate aqueous solution (1.6 L), saturated saline solution (1.6 L), and distilled water (1.6 L) and then dried using magnesium sulfate (anhydrous). After the desiccant was removed, IPE was vacuum-concentrated to obtain 285 g of a blown oily substance. This was purified with a silica gel column to obtain 222 g (yield: 81.6%) of an isopropyl form (1-(3,4-dimethoxyphenyl)-2-methylpropanone). The structure was identified by NMR and GCMS.
δ=1.22 (6H) 3.55 (1H) 3.94 (3H) 3.95 (3H) 6.90 (1H) 7.55 (1H) 7.60 (1H)

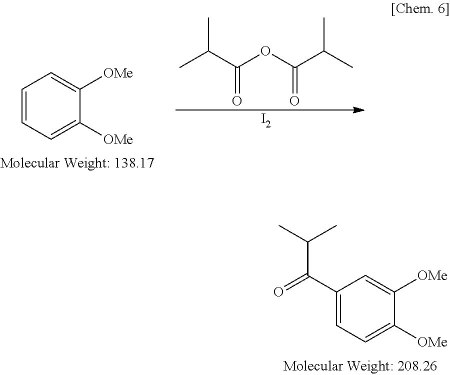

### Synthesis of nitro compound, 1-(4,5-dimethoxy-2-nitrophenyl)-2-methylpropan-1-one

The isopropyl form (50.0 g (0.024 mol, 1.00 eq.)) and acetic acid (150 mL) were mixed together. An acetic acid (100 mL) solution of 69% nitric acid was added dropwise thereto. After that, the components were heated and stirred at 50° C. for two hours, and the disappearance of the raw materials was confirmed by thin-layer chromatography (TLC). Furthermore, after that, a reaction was ended. As a reaction treatment, ice water (800 g) was poured into a reactor to quench the raw materials, and the raw materials were then transferred to a separatory funnel and washed with ethyl acetate (1 L) and water (200 mL). A water layer was separated, and a remainder was further washed with water (1 L) in a separating funnel. Next, the remainder was washed with a 5% sodium bicarbonate aqueous solution (1 L) and then dried using a desiccant. After the desiccant was removed, the remainder was vacuum-concentrated and purified with a silica gel column to obtain 38.7 g (yield: 64%) of a nitro compound (1-(4,5-dimethoxy-2-nitrophenyl)-2-methylpropan-1-one). The structure was identified by NMR and GCMS.
δ=1.22 (6H) 2.91 (1H) 3.98 (3H) 3.99 (3H) 6.69 (1H) 7.66 (1H)

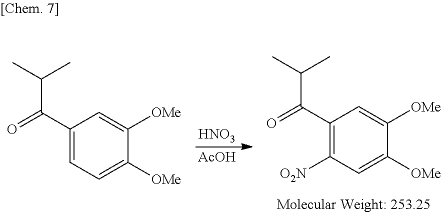

### Synthesis of isopropyl alcohol form: 1-(4,5-dimethoxy-2-nitrophenyl)-2-methylpropan-1-ol

13.8 g (54.5 mmol, 1.00 eq.) of the nitro compound, 180 mL of tetrahydrofuran (THF), and 120 mL of methanol were mixed together. After that, 4.12 g (109 mmol, 2.00 eq.) of sodium borohydride was added thereto at 0° C. After 90 minutes from the start of the addition, the components were stirred at room temperature for 30 minutes, a reaction solution was then cooled with ice water, a 5% sodium bicarbonate aqueous solution (300 mL) was added thereto, and the components were stirred for five minutes. The reaction solution was transferred to a separatory funnel, and ethyl acetate (600 mL) was extracted. An organic layer was washed with saturated saline solution (300 mL) and then dried with magnesium sulfate (anhydrous). After the desiccant was removed, the remainder was vacuum-concentrated to obtain an oily substance. This obtained crude product was purified with a silica gel column to obtain 9.38 g (yield: 67%) of an isopropyl alcohol form (1-(4,5-dimethoxy-2-nitrophenyl)-2-methylpropan-1-ol) of the yellow oily substance. The structure was identified by NMR and GCMS.
δ=0.96 (6H) 1.96 to 2.09 (1H) 2.23 (1H) 3.95 (3H) 3.99 (3H) 5.27 (1H) 7.21 (1H) 7.56 (1H)

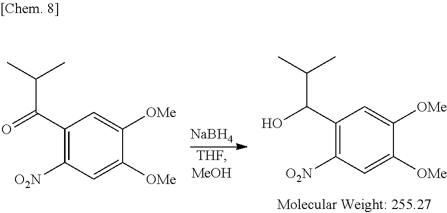

Synthesis of Monomer iPrNBC-AEMA

In an argon atmosphere, dry tetrahydrofuran (100 ml) was added to 5.00 g (19.6 mmol, 1.00 eq.) of the isopropyl alcohol form to dissolve the isopropyl alcohol form. Dibutyltin dilaurate (2.00 eq.) was added thereto, and 3.65 g (23.5 mmol, 1.20 eq.) of 2-isocyanatoethyl methacrylate was added dropwise thereto for five minutes. After that, the solution was heated up to a bath temperature of 75° C. for one hour, heated and refluxed at the same temperature for three hours. The reaction end point was confirmed by NMR and TLC, and a reaction solution was left to cool and then vacuum-concentrated to obtain 8.69 g of a yellow oily substance iPrNBC-AEMA.

The obtained crude product was again dissolved in ethyl acetate (45 mL), and n-heptane (450 mL) was added dropwise thereto. Solid was filtered and vacuum-dried, thereby obtaining 6.47 g (80.5%) of target iPrNBC-AEMA.
δ=0.98 (6H) 1.94 (4H) 2.16 (1H) 3.49 (3H) 3.95 (6H) 4.22 (2H) 4.64 (1H) 5.60 (1H) 6.12 (1H) 6.22 (1H) 6.89 (1H) 7.59 (1H)

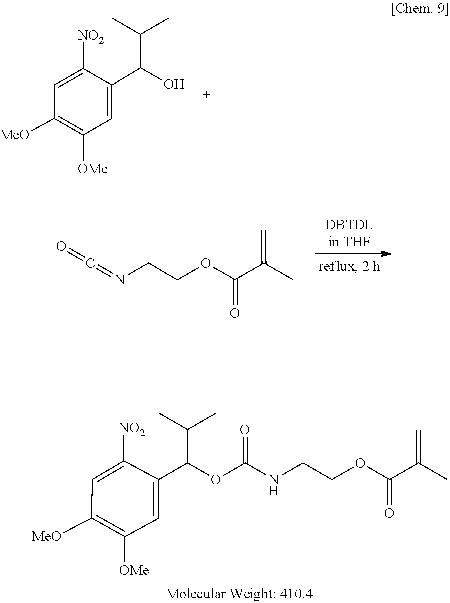 [SMILES: COc1cc(C(O)C(C)C)c([N+](=O)[O-])cc1OC ; C=C(C)C(=O)OCCN=C=O ; C=C(C)C(=O)OCCNC(=O)OC(c1cc(OC)c(OC)cc1[N+](=O)[O-])C(C)C]

### Synthesis of PiPrNBC-AEMA

In an argon atmosphere, 6.15 g (15.0 mmol, 1.00 eq.) of iPrNBC-AEMA was dissolved in 10 ml of super dehydrated DMF bubbled with Ar for 30 minutes. 0.123 g (0.75 mmol, 0.05 eq.) of AIBN was added thereto, the solution was heated up to a bath temperature of 65° C. for 30 minutes, heated and stirred at the same temperature for 21 hours. The reaction end point was confirmed by NMR, a reaction solution was left to cool and then added dropwise to methanol (240 mL), and precipitated solid was centrifuged. After a supernatant was removed, methanol (240 mL) was added again to perform centrifugation. After a supernatant was removed, a crude product was dissolved again in chloroform (40 mL) and added dropwise to methanol (400 mL). After a supernatant was removed, methanol (400 mL) was added thereto, solid and liquid were separated from each other by centrifugation, the obtained solid was vacuum-dried in a centrifuge tube, and 4.01 g of PiPrNBC-AEMA was obtained.

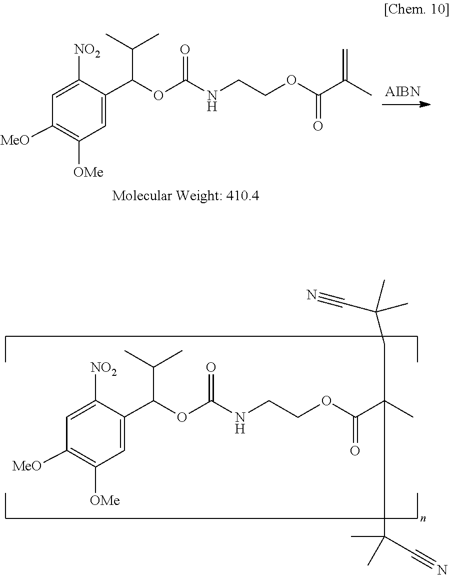

### Example 4

In the present example, the adhesion of copper-plated layers was evaluated when base films formed under a variety of conditions were used between the substrate 10 and the photosensitive resin film 12A as in FIG. 3 as a base film of the photosensitive resin film 12A.

Base films were formed on alkali-free glass substrates using an epoxy resin or a silane coupling agent under a variety of conditions as described below. After that, a cyclopentanone solution in which the concentration of PiPrNBC-AEMA (polyisopropyl nitrobenzyl carbamate) was 0.3 wt % was applied onto the base films using a spin coater (MS-A150 manufactured by Mikasa Corporation) at 1000 rpm and then heated at 100° C. for 20 minutes, thereby forming photosensitive resin films.

Next, the entire surfaces of the photosensitive resin films were exposed to UV light having a wavelength of 365 nm at 1000 mJ/cm² to sensitize the photosensitive resin films, thereby forming amine generation layers.

Next, the substrates were immersed in a catalyst solution for electroless plating (manufactured by Okuno Chemical Industries Co., Ltd.) at room temperature for five minutes to attach a catalyst (Pd) to the amine generation layers. After the surfaces were washed, the substrates were immersed in a catalyst activation solution (OPC-150 CRYSTER R manufactured by Okuno Chemical Industries Co., Ltd.) at room temperature for five minutes to activate the catalyst (Pd) attached to the amine generation layers. Subsequently, the substrates were immersed in an electroless plating solution (OPC COPPER HFS manufactured by Okuno Chemical Industries Co., Ltd.) at 40° C. for three minutes, and electroless copper was precipitated on the catalyst to form copper-plated layers.

### Adhesion Evaluation

Notches were made in a lattice shape at vertical and horizontal intervals of 2 mm on each of the formed copper-plated layers, and a tape peeling test was performed using tape. The adhesion between the glass substrate and the copper-plated layer was evaluated by the tape peeling test. In a case where peeling occurred on the entire surface, “adhesion” was evaluated to be “poor” and denoted by “B” in Table 4, and in other cases, “adhesion” was evaluated to be “favorable” and denoted by “A” in Table 4.

In the present example, the epoxy resin or the silane coupling agent present between the substrate 10 and the photosensitive resin film 12A may not always function as the gate insulation layer 11 as in FIG. 3.

### Condition A01

An epoxy resin film (SU8-3005 manufactured by MicroCHEM) was formed on alkali-free glass as a base film of a photosensitive resin film. The epoxy resin film was diluted using cyclopentanone in a proportion at which the solid content concentration of SU8-3005 reached 15 wt % and used as a coating solution. The coating solution was applied to the alkali-free glass with the spin coater (MS-A150 manufactured by Mikasa Corporation) at 1000 rpm and heated at 150° C. for five minutes to form an epoxy resin film on the entire surface of the alkali-free glass. After that, the epoxy resin film was exposed to light having a wavelength of 365 nm at 1000 mJ/cm² and heated at 150° C. for 20 minutes. The film thickness of the epoxy resin film was 850 nm.

### Condition A02

An epoxy resin film was formed by the same method as in Condition A01 except that before the photoresist resin film was formed on the epoxy resin film, which was the base film, the surface of the epoxy resin film was UV/O₃-washed for three minutes. The film thickness of the epoxy resin film was 850 nm.

### Condition A03

After alkali-free glass was UV/O₃-washed for five minutes, an epoxy resin film was formed by the same method as in Condition A02. After that, the surface of the epoxy resin film was UV/O₃-washed for three minutes in the same manner as in Example A02, and a photoresist resin film was then formed. The film thickness of the epoxy resin film was 850 nm.

### Condition A04

After an epoxy resin film and a photoresist resin film were formed by the same method as in Condition A03, a copper-plated layer was formed. After being formed, the copper-plated layer was heated at 100° C. for two minutes and subsequently heated at 150° C. for three minutes.

### Condition A05

After an epoxy resin film and a photoresist resin film were formed by the same method as in Example A03, a copper-plated layer was formed. After being formed, the copper-plated layer was heated at 100° C. for two minutes and subsequently heated at 250° C. for three minutes.

### Condition A06

An epoxy resin film (SU8-3005 manufactured by MicroCHEM) was formed on alkali-free glass as a base film of a photosensitive resin film. The epoxy resin film was diluted using cyclopentanone in a proportion at which the solid content concentration of SU8-3005 reached 10 wt % and used as a coating solution. An epoxy resin film was formed on the entire surface of the alkali-free glass using this coating solution by the same method as in Condition A04, then, exposed to light having a wavelength of 365 nm at 1000 mJ/cm² and heated at 150° C. for 20 minutes. The film thickness of the epoxy resin film was 400 nm. Other steps are the same as those in Condition A04.

### Condition A07

Condition A07 is the same as Condition A06 except that an epoxy resin film was exposed to light having a wavelength of 365 nm at 200 mJ/cm² instead of 1000 mJ/cm² in Condition A06.

### Condition A08

An epoxy resin film (SU8-3005 manufactured by MicroCHEM) was formed on alkali-free glass as a base film of a photosensitive resin film. The epoxy resin film was diluted using cyclopentanone in a proportion at which the solid content concentration of SU8-3005 reached 1 wt % and used as a coating solution. A photosensitive resin film was formed, and copper plating was performed by the same methods as in Condition A07 except that an epoxy resin film was formed on the entire surface of the alkali-free glass using this coating solution. The film thickness of the epoxy resin film was 50 nm.

### Condition A09

In Condition A09, an epoxy resin film was applied not by spin coating but by dip coating. An alkali-free glass was immersed in a solution obtained by diluting SU8-3005 using cyclopentanone in a proportion at which the solid content concentration reached 1 wt % at a rate of 10 mm/sec. After that, the solution was heated at 100° C. for five minutes to form an epoxy resin film. A substrate having the epoxy resin film formed on the entire surface was exposed to light wavelength of 365 nm at 200 mJ/cm² to be sensitized. The film thickness of the epoxy resin film was 60 nm.

In Condition A09, a photosensitive resin film that was formed on the epoxy resin film was also applied by dip coating. A cyclopentanone solution in which the concentration of PiPrNBC-AEMA (polyisopropyl nitrobenzyl carbamate) was 0.3 wt % was applied by dip coating (5 mm/sec) and heated at 100° C. for five minutes, thereby forming the photosensitive resin film.

Next, a substrate having the photosensitive resin film formed on the entire surface was exposed to light wavelength of 365 nm at 1000 mJ/cm² to form an amine generation layer. Steps performed until the subsequent formation of a copper-plated layer were the same as those in Condition A04.

### Condition A10

In the present condition, an epoxy resin film was formed by dip coating at a slower immersion rate (5 mm/sec) than in Condition A09. The others are the same as in Condition A09. The film thickness of the epoxy resin film was 20 nm.

### Condition A11

In the present condition, an epoxy resin film with which GPSC, which is an epoxysilane, had been mixed was used as a base film. The epoxy resin film was diluted using cyclopentanone in a proportion at which 3-glycidoxypropyltrimethoxysilane (GPSC manufactured by Tokyo Chemical Industry Co., Ltd.) reached 0.3 wt % and SU8-3005 (manufactured by MicroCHEM) reached 1 wt % and used as a coating solution. The coating solution was applied to alkali-free glass by spin coating at 1000 rpm and heated at 100° C. for five minutes to form an epoxy resin film with which GPSC had been mixed. After that, a substrate having the epoxy resin film formed on the entire surface was exposed to light having a wavelength of 365 nm at 200 mJ/cm². A copper-plated layer was formed by the same method as in Example A08 except what has been described above. The film thickness of the base film was 100 nm.

### Condition A12

In Condition A11, the epoxy resin film with which GPSC, which is an epoxysilane, had been mixed was used as the base film; however, in Condition A12, an epoxy resin film was laminated on GPSC as a base film. The epoxy resin film was diluted using cyclopentanone in a proportion at which 3-glycidoxypropyltrimethoxysilane (manufactured by Tokyo Chemical Industry Co., Ltd.) reached 0.3 wt % and used as a coating solution. The GPSC coating solution was applied to alkali-free glass by spin coating at 1000 rpm and heated at 150° C. for five minutes. After that, the GPSC coating solution was exposed to light having a wavelength of 365 nm at 200 mJ/cm². After a GPSC layer was formed, an epoxy resin film was formed, and a copper-plated layer was formed in the same manner as in Example A08. The film thickness of the base film was 100 nm.

### Condition B01

A silane coupling agent was applied onto alkali-free glass as a base film of a photosensitive resin film. iPrNBC-APTMOS (isopropyl nitrobenzyl carbamate-type silane coupling agent) was diluted using cyclopentanone in a proportion at which the solid content concentration reached 0.3 wt % and used as a coating solution. The coating solution containing iPrNBC-APTMOS was applied to alkali-free glass with a spin coater (MS-A150 manufactured by Mikasa Corporation) at 1000 rpm and heated at 150° C. for 10 minutes to form a silane coupling layer. A copper-plated layer was formed by the same method as in Example A01 except for the above-described step. The film thickness of the base film was 2 nm.

Hereinafter, the structure of iPrNBC-APTMOS will be shown.

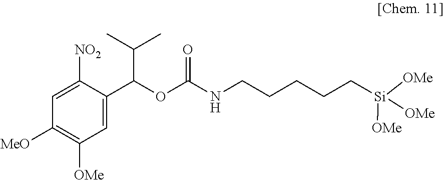 [SMILES: COc1cc(C(OC(=O)NCCCCC[Si](OC)(OC)OC)C(C)C)c([N+](=O)[O-])cc1OC]

### Condition B02

After the surface of alkali-free glass was UV/O₃-washed for five minutes, a copper-plated layer was formed by the same method as in Condition B01.

### Condition B03

Condition B03 is the same method as Condition B02 except that a copper-plated layer was formed, then, heated at 100° C. for two minutes, and then heated at 150° C. for three minutes.

### Condition C01

As a comparative condition, a copper-plated layer was formed by the same method as in Condition A01 except that an epoxy resin film was not formed on alkali-free glass.

### Condition C02

As a comparative condition, a copper-plated layer was formed by the same method as in Condition B03 except that only a GPSC layer was formed on alkali-free glass. The GPSC layer was formed with an intention of a film thickness as thin as 10 nm or less, and the average film thickness after the film formation was 5.7 nm. After that, a copper-plated layer was formed.

### Evaluation

The table and the result of adhesion evaluation for each condition are shown in Table 4. In all of Conditions A01 to A12 and B01 to B03, the adhesion was highly evaluated. In contrast, in Condition C01, the peeling of the entire surface of the copper-plated layer was observed, and it was found that the adhesion was poor. From this result, it was found that adhesion strength improves when an epoxy resin film or a silane coupling layer is provided as a base film between a glass substrate and an amine generation layer. Such a method is particularly effective in the case of using a poorly adhesive substrate that is hard to plate such as a glass substrate.

TABLE 4

| | Base film | | | | | | UV/O3 | | |
|---|---|---|---|---|---|---|---|---|---|
| | | | | Heating | | | washing | | |
| | | Film | Exposure | temperature | | | of | Heating | |
| | | forming | dose | after | UV/O3 | Film | glass | after | Adhesion |
| Condition | Material | method | (mJ/cm²) | exposure | washing | thickness | substrate | plating | evaluation |
| A01 | Epoxy | Spin | 1000 | 150 °C | — | 850 | — | — | A |
| | resin | coating | | | | nm | | | |
| | film | | | | | | | | |
| | (15 | | | | | | | | |
| | wt %) | | | | | | | | |
| A02 | Epoxy | Spin | 1000 | 150 °C | O | 850 | — | — | A |
| | resin | coating | | | | nm | | | |
| | film | | | | | | | | |
| | (15 | | | | | | | | |
| | wt %) | | | | | | | | |
| A03 | Epoxy | Spin | 1000 | 150 °C | O | 850 | O | — | A |
| | resin | coating | | | | nm | | | |
| | film | | | | | | | | |
| | (15 | | | | | | | | |
| | wt %) | | | | | | | | |
| A04 | Epoxy | Spin | 1000 | 150 °C | O | 850 | O | 100 °C→150 °C | A |
| | resin | coating | | | | nm | | | |
| | film | | | | | | | | |
| | (15 | | | | | | | | |
| | wt %) | | | | | | | | |
| A05 | Epoxy | Spin | 1000 | 150 °C | O | 850 | O | 100 °C→250 °C | A |
| | resin | coating | | | | nm | | | |
| | film | | | | | | | | |
| | (15 | | | | | | | | |
| | wt %) | | | | | | | | |
| A06 | Epoxy | Spin | 1000 | 150 °C | O | 400 | O | 100 °C→150 °C | A |
| | resin | coating | | | | nm | | | |
| | film | | | | | | | | |
| | (10 | | | | | | | | |
| | wt %) | | | | | | | | |
| A07 | Epoxy | Spin | 200 | 150 °C | O | 400 | O | 100 °C→150 °C | A |
| | resin | coating | | | | nm | | | |
| | film | | | | | | | | |
| | (10 | | | | | | | | |
| | wt %) | | | | | | | | |
| A08 | Epoxy | Spin | 200 | 100 °C | O | 50 | O | 100 °C→150 °C | A |
| | resin | coating | | | | nm | | | |
| | film (1 | | | | | | | | |
| | wt %) | | | | | | | | |
| A09 | Epoxy | Dip | 200 | 100 °C | O | 60 | O | 100 °C→150 °C | A |
| | resin | (10 | | | | nm | | | |
| | film (1 | mm/s) | | | | | | | |
| | wt %) | | | | | | | | |
| A10 | Epoxy | Dip | 200 | 100 °C | O | 20 | O | 100 °C→150 °C | A |
| | resin | (5 | | | | nm | | | |
| | film (1 | mm/s) | | | | | | | |
| | wt %) | | | | | | | | |
| A11 | GPSC | Spin | 200 | 100 °C | O | 100 | O | 100 °C→150 °C | A |
| | (0.3 | coating | | | | nm | | | |
| | wt %) + | | | | | | | | |
| | epoxy | | | | | | | | |
| | resin | | | | | | | | |
| | film (1 | | | | | | | | |
| | wt %) | | | | | | | | |
| A12 | GPSC | Spin | 200 | 100 °C | O | 100 | O | 100 °C→150 °C | A |
| | (0.3 | coating | | | | nm | | | |
| | wt %) + | | | | | | | | |
| | epoxy | | | | | | | | |
| | resin | | | | | | | | |
| | film (1 | | | | | | | | |
| | wt %) | | | | | | | | |
| B01 | iPrNB | Spin | — | — | — | 2 | — | — | A |
| | C- | coating | | | | nm | | | |
| | APTMOS | | | | | | | | |
| B02 | iPrNB | Spin | — | — | — | 2 | O | — | A |
| | C- | coating | | | | nm | | | |
| | APTMOS | | | | | | | | |
| B03 | iPrNB | Spin | — | — | — | 2 | O | 100 °C→150 °C | A |
| | C- | coating | | | | nm | | | |
| | APTMOS | | | | | | | | |
| C01 | — | — | — | — | — | — | — | — | B |
| C02 | GPSC | Spin | N/A | N/A | N/A | 5.7 | O | 100 °C→150 °C | B |
| | | coating | | | | nm | | | |

Specifically, materials capable of forming a chemical bond with an amino group in the amine generation layer are used as base films. Examples of a chemical structure that brokers the glass surface and the amino group in the amine generation layer include epoxy, alkoxysilane, isocyanate, acid anhydrides, and the like. In particular, epoxy or alkoxysilane is desirable. These materials may be used to provide underlayers as in Conditions A01 to A10 and B01 to B03. A method for forming a base film is not particularly limited, spin coating or dip coating may be used as in Conditions A01 to A10, and additionally, spray coating, roll coating, and the like can also be applied.

It is considered that a base film having an epoxy group crosslinks with a hydroxyl group in a glass substrate and enables excellent adhesion to substrates to be obtained. In addition, the epoxy group also crosslinks with the amino group in the amine generation layer and enables excellent adhesion to the amine generation layer to be obtained. Therefore, when a material having an epoxy group is used as a base film, it is possible to strengthen the adhesion between the substrate and the amine generation layer and to prevent the peeling of the copper-plated layer.

As a material that is contained in the base film, a polyfunctional epoxy group is preferable. A photosensitive epoxy composition capable of promoting a crosslinking reaction with light is preferable. A hydroxyl group on the surface of the glass substrate and the epoxy group in the epoxy resin, and the amino group in the amine generation layer and the epoxy group in the epoxy resin are capable of forming a chemical bond.

In addition, iPrNBC-APTMOS, which is a silane coupling agent, changes to a bond having an amino group and a silyl group by exposure. An amino group in a silane coupling agent has a high affinity to the amino group in the amine generation layer and increases the adhesive force therebetween. Furthermore, the silyl group forms a siloxane bond with the glass substrate and thus also enables high adhesion to the glass substrate to be obtained. Therefore, the silane coupling agent is also capable of strengthening the adhesion between the substrate and the amine generation layer and of preventing the peeling of the copper-plated layer.

In addition, in Condition C02 where the GPSC layer having an average film thickness of 5.7 nm was used as the base film, the peeling of the entire surface of the copper-plated layer was observed, and it was found that the adhesion was poor. In contrast, in the epoxy resin film of 20 nm in Condition A10, since the peeling of the copper-plated layer was not observed, and the adhesion was high, it was found that the film thickness of the base film having an epoxy group is preferably 20 nm or more.

1. A laminate comprising, in this order:
a substrate;
an amine generation layer;
a copper wire layer; and
a copper wire protective layer.

2. The laminate according to claim 1, further comprising:
a layer containing palladium between the copper wire layer and the amine generation layer.

3. The laminate according to claim 1 or 2, further comprising:
a gold-plated layer on the copper wire protective layer.

4. A transistor, comprising:
the laminate according to claim 1 or 2; and
an organic semiconductor layer.

5. A method for manufacturing a laminate, the method comprising:
a step of applying a photosensitive surface treatment agent onto a substrate to form a photosensitive resin film and exposing the photosensitive resin film to form an amine generation layer having an amine generation region in an exposure portion;
a step of forming a first catalyst layer on the amine generation layer and further performing electroless plating to form a copper-plated layer; and
a step of forming a photoresist layer on the copper-plated layer, pattern-exposing the photoresist layer to form an exposure portion corresponding to a pattern of a copper wire layer, and removing the photoresist layer in an unexposed portions.

6. The method for manufacturing a laminate according to claim 5, further comprising:
a step of removing a part of the copper-plated layer to form a copper wire layer and forming a preliminary pattern including the photoresist laver on the copper wire layer;
a step of bringing a catalyst remover into contact with the preliminary pattern to remove the first catalyst laver present in a photoresist opening portion;
a step of removing the photoresist laver on the copper wire layer; and
a step of forming a second catalyst laver on the copper wire laver and further performing electroless plating to form a copper wire protective layer.

7. The method for manufacturing a laminate according to claim 5,
the photosensitive resin film includes a photosensitive polymer indicated the following chemical formula:

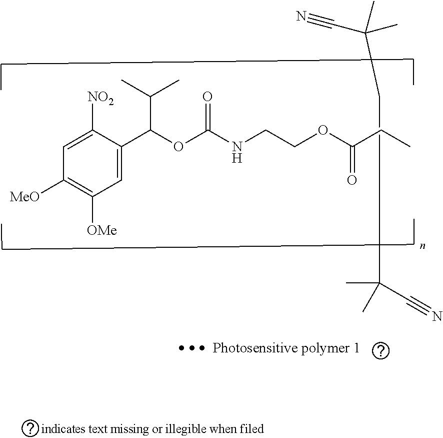

8. A method for manufacturing a transistor, the method comprising:
the method for manufacturing a laminate according to claim 5.
